(19) United States
(12) Patent Application Publication
(10) Pub. No.: US 2023/0023668 A1
(43) Pub. Date: Jan. 26, 2023

(54) BATTERY DEVICE AND BATTERY PROTECTION METHOD FOR SAME

(71) Applicant: ASUSTeK COMPUTER INC., Taipei City (TW)

(72) Inventors: Chunyen Lai, Taipei City (TW); Yu-Cheng Shen, Taipei City (TW); Chieh-Ju Yang, Taipei City (TW); Chun Tsao, Taipei City (TW); Chaochan Tan, Taipei City (TW); Huichuan Lo, Taipei City (TW)

(73) Assignee: ASUSTeK COMPUTER INC., Taipei City (TW)

(21) Appl. No.: 17/861,266

(22) Filed: Jul. 11, 2022

(30) Foreign Application Priority Data
Jul. 22, 2021 (TW) 110126970

(51) Int. Cl. H02J 7/00; H01M 10/44; H01M 10/42; G01R 31/3835

(52) U.S. Cl. CPC H02J 7/0029; H02J 7/0063; H02J 7/0048; H02J 7/00712; H02J 7/0068; H01M 10/44; H01M 10/4257; G01R 31/3835; H01M 2010/4271

(57) ABSTRACT

A battery device and a battery protection method for same are provided. It is determined, according to electrical capacity of a battery, whether a battery device communicates with an electronic device, and whether the battery is being charged or discharged, whether to control the battery device to enter a shutdown mode.

### CROSS-REFERENCE TO RELATED APPLICATION

This application claims the priority benefit of Taiwan Application Serial No. 110126970, filed on Jul. 22, 2021. The entirety of the above-mentioned patent application is hereby incorporated by reference herein and made a part of specification.

### BACKGROUND OF THE INVENTION

### Field of the Invention

The disclosure relates to a battery device and a battery protection method for same.

### Description of the Related Art

In a case that an electronic product has not been used for a long time, a capacity of a battery keeps decreasing due to continuous self-consumption of a system and the battery. In this case, copper precipitation occurs when the capacity of the battery decreases to an extreme low capacity. When copper precipitation occurs, crystals precipitate and puncture an isolating film to cause a short circuit during charging of the battery. Therefore, when the battery has an extreme low electrical capacity, deep discharge protection needs to be activated to prevent the battery from failing.

### BRIEF SUMMARY OF THE INVENTION

According to the first aspect, a battery device is provided. The battery device includes a battery and a control chip. The control chip is coupled to the battery, and is configured to: measure an electrical capacity of the battery, and control the battery device to enter a shutdown mode. The control chip determines, according to the electrical capacity of the battery, whether the battery device communicates with an electronic device, and whether the battery is being charged or discharged, whether to control the battery device to enter the shutdown mode.

According to the second aspect, a battery protection method for a battery device is provided. The battery device is configured to supply electric power to an electronic device. The battery device includes a battery. The battery protection method for a battery device includes the following steps: measuring an electrical capacity of the battery; determining whether the electrical capacity of the battery is less than a preset capacity; determining whether the battery device communicates with the electronic device; and determining whether the battery is being charged or discharged. When the electrical capacity of the battery is less than the preset capacity, the battery device does not communicate with the electronic device, and the battery is not being charged or discharged, the control chip controls the battery device to enter a shutdown mode.

Based on the above, in the disclosure, it is determined, according to the electrical capacity of the battery, whether the battery device communicates with the electronic device, and whether the battery is being charged or discharged, whether to control the battery device to enter the shutdown mode. When the electrical capacity of the battery is less than the preset capacity, the battery device does not communicate with the electronic device, and the battery is not being charged or discharged, the battery device is directly controlled to enter the shutdown mode to make the battery device perform deep discharge protection in advance. In this way, self-consumption of the battery device is significantly decreased and an allowable time for an electronic product to be left unused is extended. Therefore, the battery is effectively protected and prevented from failing.

### BRIEF DESCRIPTION OF THE DRAWINGS

FIG. 1 is a schematic diagram of a battery device according to an embodiment of the disclosure.

FIG. 2 is a relationship diagram of a total consumption current of a battery and time according to an embodiment of the disclosure.

FIG. 3 is a relationship diagram of a capacity of a battery and time according to an embodiment of the disclosure.

FIG. 4 is a flowchart of a battery protection method for a battery device according to an embodiment of the disclosure.

### DETAILED DESCRIPTION OF THE EMBODIMENTS

In order to make the content of the disclosure understood more easily, embodiments are specifically provided below as examples for the disclosure to be implemented. In addition, where possible, elements/components/steps with the same labels in the drawings and implementations represent the same or similar parts.

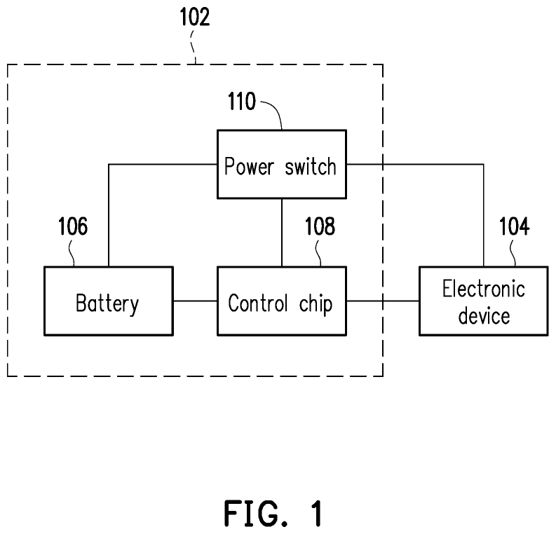

Referring to FIG. 1, a battery device 102 supplies electric power to an electronic device 104. In an embodiment, the electronic device 104 is a portable electronic device such as a notebook computer or a mobile phone. The disclosure is not limited thereto. The battery device 102 includes a battery 106, a control chip (gauge IC) 108, and a power switch 110. The battery 106 is coupled to the control chip 108. The power switch 110 is coupled to the battery 106, the control chip 108, and the electronic device 104. It is to be noted that, in this embodiment, the battery device 102 is externally connected to the electronic device 104. In another embodiment, the battery device 102 is integrated into the electronic device 104. However, this embodiment is not limited thereto.

The control chip 108 measures an electrical capacity of the battery 106, and determines, according to the electrical capacity of the battery 106, whether the battery device 102 communicates with the electronic device 104, and whether the battery 106 is being charged or discharged, whether to control the battery device 102 to enter a shutdown mode. In an embodiment, the control chip 108 obtains the electrical capacity of the battery 106 by measuring a voltage of the battery 106. In an embodiment, the battery device 102 communicates with the electronic device 104 through a system bus. The disclosure is not limited thereto. In an embodiment, the control chip 108 transmits an electrical capacity measuring signal to the electronic device 104 through the system bus to make the electronic device 104 obtain the electrical capacity of the battery 106. In addition, whether the battery 106 is being charged or discharged means whether the battery 106 is being charged or discharged in response to a charge or discharge control instruction of the control chip 108 or the electronic device 104. The battery 106 supplies the electric power to the electronic device 104 through the power switch 110.

When the electrical capacity of the battery 106 is less than the preset capacity, the battery device 102 does not communicate with the electronic device 104, and the battery 106 is not being charged or discharged, the control chip 108 and the power switch 110 enter the shutdown mode to make the battery device 102 directly perform deep discharge protection. Compared with the prior art in which power consumption of the battery device 102 is decreased progressively, the battery device 102 in this embodiment directly minimizes the power consumption of the battery device 102, thereby extending an allowable time for the battery device 102 and the electronic device 104 to be left unused. In this way, the battery is effectively protected and prevented from failing.

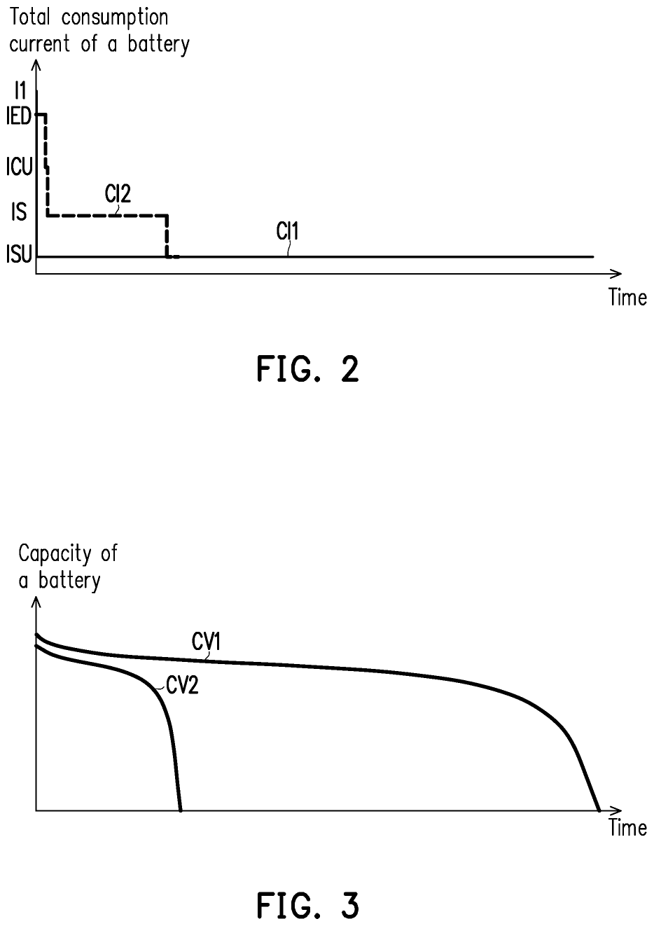

Further, when the voltage of the battery 106 decreases to a preset voltage of the battery 106 corresponding to the preset capacity (in an embodiment, the preset capacity is any value from 0% to 5%, but is not limited thereto), the control chip 108 directly disconnects the power switch 110 and decreases self-power consumption to enter a low energy consumption state. Referring to FIG. 2, a curve CI1 is a change curve of a corresponding total consumption current of the battery when the battery device in the embodiment of the disclosure performs battery protection. A curve CI2 is a change curve of a corresponding total consumption current of a battery when a conventional battery device performs battery protection. The total consumption current of the battery includes a consumption current supplied by the battery device 102 to the electronic device 104 and an internal consumption current of the battery device 102. According to the curve CI1 in FIG. 2, when the control chip 108 disconnects the power switch 110 and enters the low energy consumption state, the total consumption current of the battery 106 directly decreases from a current I1 to a corresponding current ISU when deep discharge protection is performed, thereby significantly decreasing self-consumption of the battery device 102. In an embodiment, in the low energy consumption state, the control chip 108 receives only an operating voltage required for wakeup. In some embodiments, the battery device 102 decreases the self-consumption of the battery device 102 by removing a power voltage required for operation of the control chip 108 or cutting off a power supply path of the control chip 108.

However, in the conventional battery device, the total consumption current of the battery gradually decreases as the electrical capacity of the battery decreases. According to the curve CI2 in FIG. 2, the total consumption current of the battery of the conventional battery device decreases in a plurality of stages as the electrical capacity of the battery decreases. When the electrical capacity decreases to the preset capacity, the battery device has an insufficient electrical capacity and fails to supply the consumption current to the electronic device 104. At this point, a total consumption current IED of the battery of the battery device is equal to the internal consumption current of the battery device. When the electrical capacity of the battery device decreases to an electrical capacity at which low voltage protection is required, the total consumption current of the battery decreases to a current ICU. When the electrical capacity of the battery device decreases to an electrical capacity at which the battery voltage needs to be turned off, the total consumption current of the battery is decreased to a current IS. When the electrical capacity of the battery device decreases to an electrical capacity at which deep discharge protection is required, the total consumption current of the battery is decreased to the current ISU.

Referring to FIG. 3, the curve CV1 is a change curve of a capacity of the battery of the battery device in the embodiment of the disclosure. The curve CV2 is a change curve of the capacity of the battery of the conventional battery device. Referring to FIG. 2 and FIG. 3, when the voltage of the battery 106 decreases to the preset voltage, the battery device 102 in the embodiment of the disclosure directly decreases the total consumption current of the battery 106 to the corresponding current ISU when deep discharge protection is performed. Therefore, compared with the conventional battery device that decreases the total consumption current of the battery in a plurality of stages, attenuation of the capacity of the battery is effectively slowed down and the allowable time for the battery device 102 and the electronic device 104 to be left unused is extended. In this way, the battery is effectively protected and prevented from failing.

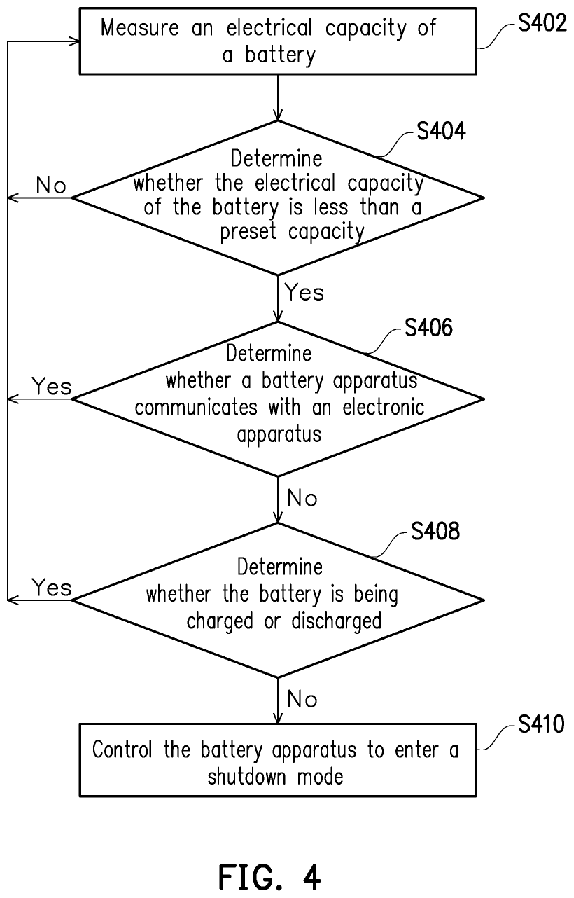

Referring to FIG. 4, it is known from the foregoing embodiment that the battery protection method for a battery device at least includes the following steps. First, the electrical capacity of the battery is measured (step S402). In an embodiment, the electrical capacity of the battery is obtained by measuring the voltage of the battery. Next, it is determined whether the electrical capacity of the battery is less than the preset capacity (step S404). In an embodiment, it is determined, according to whether the voltage of the battery is less than the preset voltage, whether the electrical capacity of the battery is less than the preset capacity. In a case that the electrical capacity of the battery is not less than the preset capacity, the electrical capacity of the battery continues to be measured. In a case that the electrical capacity of the battery is less than the preset capacity, it is determined whether the battery device communicates with the electronic device (step S406), in an embodiment, whether the battery device communicates with the electronic device through the system bus, and in another embodiment, whether the electrical capacity measuring signal is transmitted to the electronic device through the system bus. The disclosure is not limited thereto. In a case that the battery device communicates with the electronic device, the electrical capacity of the battery continues to be measured. In a case that the battery device does not communicate with the electronic device, it is determined whether the battery is being charged or discharged (step S408), in an embodiment, whether the battery is being charged or discharged in response to the charge or discharge control instruction of the control chip or the electronic device. In a case that the battery is being charged or discharged, the electrical capacity of the battery continues to be measured. In a case that the battery is not being charged or discharged, the battery device is controlled to enter the shutdown mode (step S410).

In the shutdown mode, the power switch of the battery device is disconnected to prevent the battery of the battery device from supplying electric power to the electronic device through the power switch. In addition, the control chip of the battery device is enabled to enter the low energy consumption state to decrease the total consumption current of the battery to the corresponding total consumption current of the battery when deep discharge protection is performed. In this way, the self-consumption of the battery device is significantly decreased and the allowable time for the battery device and the electronic device to be left unused is extended. Therefore, the battery is effectively protected and prevented from failing. In the low energy consumption state, the control chip receives, for example, only the operating voltage required for wakeup. In some embodiments, the battery device decreases the self-consumption of the battery device by removing the power voltage required for the operation of the control chip or cutting off the power supply path of the control chip.

In summary, in the disclosure, it is determined, according to the electrical capacity of the battery, whether the battery device communicates with the electronic device, and whether the battery is being charged or discharged, whether to control the battery device to enter the shutdown mode. When the electrical capacity of the battery is less than the preset capacity, the battery device does not communicate with the electronic device, and the battery is not being charged or discharged, the battery device is directly controlled to enter the shutdown mode (in the shutdown mode, the power switch is disconnected and the control chip is in the low energy consumption state) to make the battery device perform deep discharge protection in advance. In this way, the self-consumption of the battery device is significantly decreased and an allowable time for an electronic product to be left unused is extended. Therefore, the battery is effectively protected and prevented from failing. In this way, even though the electronic device is left unused for a long time, the battery is still chargeable to make the battery device supply electric power to the electronic device normally.

The disclosure has been disclosed above with embodiments; however, the embodiments are not intended to limit the disclosure. Any person of ordinary skill in the art can make some changes and modifications without departing from the spirit and scope of the disclosure. Thus, the protection scope of the disclosure should be subject to that defined by the appended claims.

What is claimed is:

1. A battery device, configured to supply electric power to an electronic device, and comprising:
a battery; and
a control chip, coupled to the battery, and configured to: measure an electrical capacity of the battery, and control the battery device to enter a shutdown mode,
wherein the control chip determines, according to the electrical capacity of the battery, whether the battery device communicates with the electronic device, and whether the battery is being charged or discharged, whether to control the battery device to enter the shutdown mode.

2. The battery device according to claim 1, wherein when the electrical capacity of the battery is less than a preset capacity, the battery device does not communicate with the electronic device, and the battery is not being charged or discharged, the control chip controls the battery device to enter the shutdown mode.

3. The battery device according to claim 1, further comprising:
a power switch, coupled to the battery, the electronic device, and the control chip, wherein the battery supplies the electric power to the electronic device through the power switch, and the control chip disconnects the power switch to enter a low energy consumption state.

4. The battery device according to claim 1, wherein the control chip determines, according to whether a voltage of the battery is less than a preset voltage, whether the electrical capacity of the battery is less than the preset capacity.

5. The battery device according to claim 1, wherein the battery device communicates with the electronic device through a system bus.

6. A battery protection method for a battery device, wherein the battery device is configured to supply electric power to an electronic device, the battery device comprises a battery, and the battery protection method for a battery device comprises:
measuring an electrical capacity of the battery;
determining whether the electrical capacity of the battery is less than a preset capacity;
determining whether the battery device communicates with the electronic device;
determining whether the battery is being charged or discharged; and
when the electrical capacity of the battery is less than the preset capacity, the battery device does not communicate with the electronic device, and the battery is not being charged or discharged, controlling the battery device to enter a shutdown mode.

7. The battery protection method for a battery device according to claim 6, wherein the battery device further comprises a power switch and a control chip, the power switch is coupled to the battery, the electronic device, and the control chip, the battery supplies the electric power to the electronic device through the power switch, and the battery protection method for a battery device comprises:
disconnecting the power switch and making the control chip enter a low energy consumption state in the shutdown mode.

8. The battery protection method for a battery device according to claim 6, comprising:
determining, according to whether a voltage of the battery is less than a preset voltage, whether the electrical capacity of the battery is less than the preset capacity.

9. The battery protection method for a battery device according to claim 6, wherein the battery device communicates with the electronic device through a system bus.
